(19) United States
(12) Patent Application Publication
(10) Pub. No.: US 2015/0031202 A1
(43) Pub. Date: Jan. 29, 2015

(54) METHOD FOR MANUFACTURING SEMICONDUCTOR WAFERS

(71) Applicant: Altatech Semiconductor, Montbonnot-Saint-Martin (FR)

(72) Inventors: Julien Vitiello, Grenoble (FR); Jean-Luc Delcarri, Saint Ismier (FR)

(21) Appl. No.: 14/382,731

(22) PCT Filed: Mar. 8, 2013
(86) PCT No.: PCT/FR2013/050491

§ 371 Date: Sep. 3, 2014

(30) Foreign Application Priority Data
Mar. 12, 2012 (FR) 1200753

(51) Int. Cl. H01L 21/768; H01L 21/02

(52) U.S. Cl. CPC H01L 21/76898; H01L 21/76843; H01L 21/76802; H01L 21/76834; H01L 21/02164; H01L 21/02271; H01L 21/76879
USPC 438/653

(57) ABSTRACT

The invention relates to a method for manufacturing a semiconductor wafer including a conductive via extending from a main surface of the wafer, said the via having a shape factor greater than five, the wafer including a dielectric layer, the method including: producing, by means of deep etching, at least one recess in the semiconductor wafer, the recess extending from the main surface of the wafer and having a shape factor greater than five, the recess including a side surface; forming at least one dielectric layer in the recess, including two treatments in a controlled-pressure reactor, one of said the treatments including the chemical vapor deposition, at sub-atmospheric pressure, of a dielectric onto the side surface of the recess, the chemical deposition being carried out at a temperature lower than 400° C. and at a pressure greater than 100 Torr in the reactor, and another of the treatments including the plasma-enhanced chemical vapor deposition of a dielectric onto the side surface of the recess, the chemical deposition being carried out at a pressure of less than 20 Torr in the reactor; and filling the recess with a conductive material, thus forming a via.

### CROSS-REFERENCE TO RELATED APPLICATIONS

This application is a national phase entry under 35 U.S.C. §371 of International Patent Application PCT/FR2013/050491, filed Mar. 8, 2013, designating the United States of America as International Patent Publication WO 2013/135999 A1 on Sep. 19, 2013, which claims the benefit under Article 8 of the Patent Cooperation Treaty and under 35 U.S.C. §119(e) to French Patent Application Serial No. 1200753, filed Mar. 12, 2012, the disclosure of each of which is hereby incorporated herein in its entirety by this reference.

### TECHNICAL FIELD

The invention concerns the manufacture of semiconductor wafers with three-dimensional integration.

### BACKGROUND

After seeking to increase the number of transistors on a given surface of a semiconductor wafer, it is now being sought to stack semiconductor devices one on top of the other to increase the number thereof.

A transistor is generally formed on a substrate in single-crystal silicon of relative large thickness above which interconnects are formed of relative narrow thickness isolated by polysilicon or silicon oxide. Interconnects may have several levels. The conductive elements of one level may be connected to conductive elements of another adjacent level via a vertical element called a via in copper for example. An interconnection via often has a diameter smaller than its depth, see U.S. Pat. No. 5,807,785. The form factor is then said to be less than one. Via filling difficulties already raised problems.

Document WO 2005/064651 in FIGS. 2A to 3B shows examples of trench filling with the risk of partial filling using chemical vapor deposit (CVD) or sub-atmospheric chemical vapor deposit (SACVD). This document is adapted for interconnect vias.

For three-dimensional integration of semiconductor devices e.g. transistors it is desirable to form connections over considerably greater depths, passing through the thickness of the wafer. For space-related reasons along the plane of the wafer it is not desirable to have large via diameters. These connections passing through a wafer are also called “vias”, although they use a different approach and are confronted by technological obstacles currently being researched.

One of the difficulties is that an often used metal conductor, copper, tends to diffuse in the single-crystal silicon of the substrate. Such diffusion may harm the functioning of the adjacent semiconductor device.

There exists a technique known as “Shallow Trench Isolation” or STI. This technique uses isolators arranged in trenches of the substrate. The trench hollowed in the silicon is filled with isolator. The isolators do not tend to diffuse in the substrate modifying the electric properties thereof. Trench filling is performed at high temperature before fabricating an adjacent transistor. The STI technique cannot therefore be applied to wafer vias.

The difficulties raised for wafer vias are different due to the capability of the conductive materials, in general metal, to migrate towards the single-crystal silicon of the wafer making it more conductive, this possibly causing adjacent semiconductor devices to become inoperative, and to the need to for via formation to be performed at low temperature to preserve pre-existing adjacent semiconductor structures whilst obtaining an electrically insulating layer the variation in thickness of which is limited. Reference can be made to the article: “Through Silicium Via Technology—Processes and Reliability for Wafer—Level 3D System Integration” by P. Ramm, M. J. Wolf, E. Klumpp, R. Wieland, B. Wunderle and B. Michel, published in Electronic Components and Technology Conference 2008, pages 841-846.

### BRIEF SUMMARY

For a wafer via according to the invention, the sidewalls must be lined with a layer having best possible uniformity of thickness and at low temperature.

There is a need for a through wafer via which is conductive whilst being electrically insulated from the wafer and chemically isolated to prevent pollution of the wafer by a conductive species such as copper.

The invention brings an improvement to the situation.

The invention lies within CVD processes dedicated to the preparation of such through wafer vias.

The invention concerns a method for fabricating a semiconductor wafer comprising a conductive through via extending from a main surface of the wafer, the via having a form factor higher than 5. The wafer comprises a dielectric layer. The method comprises the forming of at least one through hole, by deep etching, having a form factor higher than 5 in the semiconductor wafer. The through hole comprises a side surface. The method also comprises the forming of at least one dielectric layer in the through hole, comprising two treatments in a reactor under controlled pressure:
one treatment including sub-atmospheric chemical vapor deposit of a dielectric on the side surface of the hole, chemical deposition being conducted at a temperature lower than 400° C. and at a pressure higher than 100 Torr in the reactor;
one treatment which includes plasma-enhanced chemical vapor deposit of a dielectric on the side surface of the hole, the chemical deposit being conducted at a pressure lower than 20 Torr in the reactor. The method also comprises the filling of the hole with a conductive material thereby forming a via.

Filling takes place after the forming of the dielectric layer. A through wafer via is thus formed of regular shape and hence of low electric resistance. The dielectric layer formed in two treatments has high conformity with the side surface of the hole. The thickness of the dielectric layer is generally thinner close to the bottom of the hole and thicker in the vicinity of the edge of the hole, the ratio between these two thicknesses being greater than 55%. At any point of the side surface, the thickness is 30%, preferably 40% greater than the thickness of the dielectric layer on the main surface 2.

In one embodiment the conductive material contains copper.

In one embodiment, the dielectric layer contains silicon dioxide. Benefit is drawn from the excellent permittivity of this material.

In one embodiment the semiconductor wafer contains single-crystal silicon.

In one embodiment, the dielectric layer has a substantially cylindrical side surface. There is a tendency to obtain a so-called “conforming” dielectric deposit on the sidewall of the hole with values in the order of 30 to 40% and higher (compared with the thickness deposited on the top surface) at deposit temperatures lower than 400° C. The dielectric layer can smooth irregularities related to the deep etching process.

In one embodiment, sub-atmospheric chemical vapor deposit is performed on the semiconductor wafer before plasma-enhanced chemical vapor deposit. Plasma-enhanced chemical vapor deposit adds a second dielectric sub-layer to a first dielectric sub-layer obtained by sub-atmospheric chemical vapor deposit. By side surface of the hole is meant the free side surface during the step or sub-step under consideration.

In one embodiment sub-atmospheric chemical vapor deposit is performed on the semiconductor wafer after plasma-enhanced chemical vapor deposit. Sub-atmospheric chemical vapor deposit adds a second dielectric sub-layer to a first dielectric sub-layer obtained by plasma-enhanced chemical vapor deposit.

In one embodiment, at least one treatment is implemented at a deposit rate faster than 250 nanometers per minute, preferably than 300 nanometers per minute.

In one embodiment, after the forming of the dielectric layer, the method comprises the forming of a metal layer on the dielectric layer. The metal layer forms a barrier blocking the diffusion of the conductive material, the metal layer containing at least one from among: Ti, TiN, Ta, TaN, and Ru.

In one embodiment, the etching step of the hole comprises deep etching starting from the main surface.

According to another aspect the invention concerns a method for preparing a metal connection via successive deposition in a reactor under controlled pressure, on a semiconductor wafer comprising at least one hole substantially perpendicular to a main surface of the semiconductor wafer, the hole having a form factor higher than 5. The method comprises:
conducting sub-atmospheric chemical vapor deposit of a dielectric layer on a free inner surface of the hole, the dielectric layer having a minimum thickness 30% greater than the thickness of the dielectric layer on the main surface, chemical deposit being performed at a temperature lower than 400° C. and at a pressure higher than 100 Torr in the reactor;
conducting plasma-enhanced chemical vapor deposit of a dielectric layer of similar composition on a free inner surface of the hole, plasma-enhanced chemical vapor deposit being performed at a pressure lower than 20 Torr in the aid reactor; and
filling the holes with conductive material.

The hole may have a temporary or final bottom depending on other intended subsequent steps. The bottom of the recess is generally electrically conductive and connected to the via, optionally after polishing.

By form factor herein is meant the ratio of height to diameter.

The method can be conducted in a chemical gas deposit reactor such as described in WO 2012/013869 to which the reader is invited to refer.

### BRIEF DESCRIPTION OF THE DRAWINGS

The present invention will be better understood on examining the detailed description of some embodiments taken as examples that are in no way limiting and illustrated by the appended drawings in which:

FIG. 1 is a cross-section of a semiconductor device provided with a through hole in the progress of fabrication;

FIG. 2 is a cross-section of the semiconductor device in FIG. 1 at a later step;

FIG. 3 is a cross-section of the semiconductor device in FIG. 1 at a later step; and

FIG. 4 is a cross-section of a semiconductor device provided with a through via.

### DETAILED DESCRIPTION

The drawings and descriptions below mainly contain elements of definite nature. They can therefore not only be used to give a better understanding of the invention but can also contribute to the definition thereof when necessary.

The invention is not limited to the examples of method and apparatus described herein given solely as examples, but encompasses all variants which could be envisaged by the person skilled in the art within the scope of the claims hereof.

3D integration in CMOS technologies offers prospects of reducing the sizes of transistors and of reaching performance in terms of reduced propagation delay and limited energy consumption. The use of Through Silicon Vias (TSVs) in a substrate with these 3D technologies allows high density stacking of chips whilst continuing to have contacts with low electric resistance. Fabrication is based on 3 main steps: forming of the hole, depositing of an interface and filling of the via. The intermediate step of interface deposit is critical since first the defects of the deep etching step in the silicon must be corrected or covered and secondly the diameter of the via must be maintained to allow filling with copper by chemical deposit at the third step. This interface has several functions as electric insulator, copper diffusion barrier and adhesion promoter between the silicon and copper pad. It may be composed of a barrier layer to block diffusion of the copper and of an electrically insulating SiO₂ layer that is thicker than the barrier layer. The insulating layer is an important element to obtain the required electric performance of through wafer vias having a folio factor greater than 5:1. A solution has been developed for via integration allowing the depositing of a dielectric layer in these via holes with high form factor, deposition being the last operation and conducted at a deposit temperature limited to low values.

Each of the criteria—insulation, uniformity with high form factor, low temperature—taken alone can currently be met using one of the conventional oxide deposition techniques applied for semiconductors such as PECVD (Plasma Enhanced CVD), SACVD (sub-atmospheric pressure CVD), HPCVD (High Pressure CVD), LPCVD (Low Pressure CVD), APCVD (Atmospheric Pressure CVD) . . . but without meeting the other criteria. According to the analysis made by the inventors, the LPCVD technique allows an insulating layer of excellent quality to be obtained (dielectric, uniformity) but at a low growth rate and very high deposit temperature having regard to the intended application (>500° C.). The APCVD technique does not allow a good quality insulating layer to be obtained at temperatures lower than 400° C., whilst imposing a low growth rate. The PECVD technique allows a fast deposit rate, operation at low temperature through the use of plasma but it does not allow uniform filling of the vias with an aspect ratio higher than 5:1. Finally HPCVD deposit is characterized by very good conformity, compatible with low temperature but with low dielectric properties.

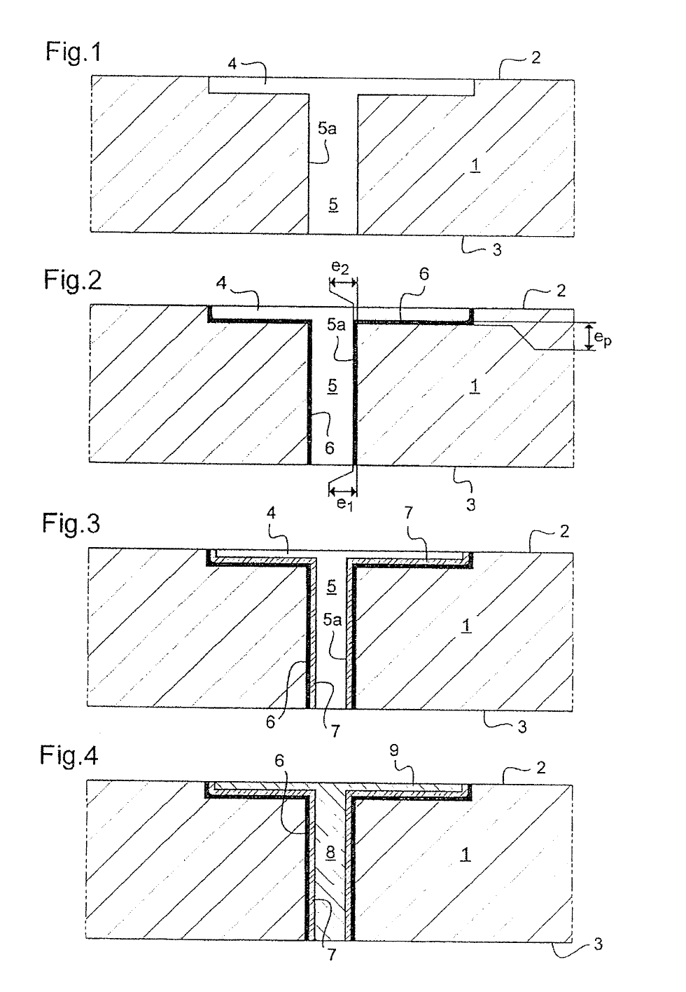

As can be seen in FIG. 1, a semiconductor wafer 1 or substrate in cross-section comprises a main surface 2, an opposite surface 3 and side edges. The side edges are arbitrarily shown here for illustration needs but do not exclude the fact that the wafer may be wider. In practice a semiconductor wafer is a disc of normalized diameter e.g. 200 or 300 mm. The main surface 2 here is in top position and the opposite surface 3 in bottom position. The main surface 2 is so called since the method is essentially performed starting from this surface. In general the semiconductor wafer 1 comprises a basic body in single-crystal silicon.

Semiconductor devices may be present in the semiconductor wafer 1, obtained at prior fabrication steps. The reader is invited to refer to the aforementioned article by Ramm. The presence of semiconductor devices imposes strong temperature constraints to prevent reactivation of the dopants thereof and modification and even destruction of their characteristics. It is desirable not to apply a temperature higher than 500° C., preferably 400° C.

The semiconductor wafer 1, starting from the top surface 2, has a basin 4. The basin 4 is shallow compared to its large surface. The basin 4 can be obtained using an etch technique. In general the basin 4 is optional. A hole 5 is made starting from the top surface 2, here in the basin 4, in the direction of the bottom surface 3. The hole 5 is a through hole. The hole 5 is formed using a deep etching technique e.g. fluorinated plasma dry etching. The hole 5 opens onto an underlying conductive element not illustrated. The underlying conductive element forms the bottom of the hole 5. The underlying conductive element may act as etch stop layer. The hole 5 comprises a side surface 5a or wall of circular cross-section (revolution). The side surface 5a is substantially cylindrical with possible corrugations depth-wise. The diameter of the hole 5 is smaller than the minimum length and width of the basin 4, for example 10% smaller than this minimum, for example 5%.

On the semiconductor wafer 1, a dielectric layer 6 is deposited, preferably SiO₂. Deposition comprises two treatments. The treatments are performed in the same reactor cf. WO2012/013869. The dielectric layer 6 is formed on the side surface 5a of the hole 5. The dielectric layer 6 may be formed on the basin 4.

The two treatments may deposit chemically identical materials. The two treatments follow after one another maintaining pressure between each treatment i.e. the pressure remains between the pressure of one and the pressure of the other.

The inventors have found that a combination of two of the aforementioned techniques in one same reactor, performing the two processes in sequence: PECVD+HPCVD or HPCVD+PECVD allows quality results to be obtained far above the superimposing of two insulating sub-layers. The choice of order of sequence is dictated by the type of via to be filled e.g. PECVD first if the via is narrowed close to the main surface, the surface condition after etching, e.g. HPCVD first if the surface of the hole is rather rough; and by the density of the via network on the substrate for example HPCVD first if the network is dense and PECVD first if the network is wide.

The advantage for through wafer vias is the following:
The sub-layer deposited by PECVD improves the dielectric performance of the assembly with low temperature deposition, in particular by densifying the prior HPCVD deposit and limiting its moisture uptake;
The sub-layer deposited by HPCVD allows the depositing of an oxide over the entire height of the via walls that is uniform to guarantee homogeneous dielectric properties. This conformity also allows reduction of the overhang effect at the top of the vias, this being a limiting factor for copper filling at subsequent steps (masking effect). It also allows the offsetting of etch-induced defects by smoothing such defects;
Overall satisfactory deposition rate (>300 nm/min), and uniformity in accordance with production needs.

One treatment comprises plasma-enhanced chemical vapor deposit at a temperature between 200 and 400° C., preferably between 200 and 300° C., at a pressure of between 2 and 20 Torr, preferably between 2 and 15 Torr, more preferably between 5 and 10 Torr, with a plasma energy of between 300 and 1200 W, preferably between 500 and 800 W, and a precursor flow of between 500 and 2000 mg/minute, preferably between 1000 and 1500 mg/minute. The O₂ and O₃ oxygen flow is between 500 and 1500 scc/minute, preferably between 800 and 1200 scc/minute, scc standing for standard centimeter cube as used in microelectronics with 10 to 18% O₃, preferably between 12 and 16% O₃. The plasma is generated by RF at a frequency between 10 and 20 MHz, preferably between 12 and 15 MHz.

Another treatment comprises sub-atmospheric chemical vapor deposit at a temperature between 200 and 400° C., preferably between 250 and 350° C., at a pressure between 100 and 600 Torr, preferably between 200 and 400 Torr, and a precursor flow between 500 and 2000 mg/minute, preferably between 1000 and 1500 mg/minute. The oxygen flow O₂ and O₃ is between 1000 and 3000 scc/minute, preferably between 1500 and 2000 scc/minute, with 10 to 18% O₃, preferably 12 to 16% O₃. The above-mentioned sub-atmospheric chemical vapor deposition is efficient for good uniformity of the sub-layer and electrical insulation.

The dielectric layer 6 covers the side wall of the hole 5. The dielectric layer 6 offers an ideally cylindrical inner surface, in practice slightly tapered thinner—e₁—close to the bottom of the hole 5, and thicker—e₂—close to the main surface 2. The dielectric layer 6 is even thicker on the main surface 2 having a thickness eₚ. The thickness e₁ may be 30%, preferably 40% thicker than thickness eₚ. Thickness e₂ may be 50%, preferably 60% thicker than thickness eₚ. The ratio e₁/e₂ is an indicator of deposit conformity. The ideal e₁/e₂ ratio is 1. The actual e₁/e₂ ratio is higher than 55%, preferably 65%. In FIG. 2, the thickness of the dielectric layer 6 has been largely exaggerated and the dielectric layer 6 illustrated is ideal i.e. cylindrical.

The dielectric layer 6 covers the single-crystal silicon of the wafer body, for example entirely.

The semiconductor wafer 1 illustrated in FIG. 2 is obtained. The dielectric layer 6 has a thickness of between 100 nm and 1000 nm, preferably between 200 and 500 nm, for example 200 nm. The dielectric layer 6 on the side surface 5a is of decreasing thickness as it moves away from the top surface 2. The drift i.e. the ratio of variation in thickness to form factor may be lower than 16%; i.e. (Max. Thickness−Min. Thickness)/Min. thickness/form factor <16%, preferably <10%, even 6%. The sub-layers provided by the treatments may fuse together.

On the semiconductor wafer 1 a barrier layer 7 is deposited. This deposit can be isotropic e.g. by CVD, or directed e.g. by PVD. The barrier layer 7 comprises a metal or metal nitride scarcely able to diffuse in the single crystal silicon. The barrier layer 7 comprises at least one of the following constituents: titanium, titanium nitride, tantalum, tantalum nitride, and ruthenium. The barrier layer 7 may be electrically conductive if it is in titanium, tantalum and ruthenium or electrically insulating if it is in a metal nitride. The barrier layer 7 is formed on the side surface 5a. The barrier layer 7 is formed on the basin 4. The thickness of the barrier layer 7 is between 1 and 100 nm, preferably between 5 and 15 nm, for example 10 nm. In FIGS. 3 and 4, the thickness of the barrier layer 7 is considerably exaggerated. In fact the thickness of the barrier layer 7 is 10 to 100 times thinner than the thickness of the dielectric layer 6. The barrier layer 7 covers the dielectric layer 6, for example entirely.

This leads to obtaining the semiconductor wafer 1 illustrated in FIG. 3. In FIG. 3, the thickness of the barrier layer 7a is largely exaggerated and the illustrated barrier layer 7 is ideal i.e. cylindrical.

On the semiconductor wafer 1 a conductive material is deposited e.g. copper. The conductive material is deposited using a uniform PVD technique (Physical Vapor Deposition) followed by electroplating. The conductive material fills the hole 5 thereby forming a via 8. The conductive material fills the basin 4 forming an electric contact or pad 9. In this manner a via of great depth is obtained, having low electric resistance, low risk of diffusion in the body of the substrate and of regular shape. The opposite surface 3 of the semiconductor wafer 1 can then be polished. Polishing removes the insulator and the barrier material deposited at the bottom of the hole. Polishing exposes the end of the conductive material in the via. It is therefore possible electrically to connect the end of the via lying flush with the opposite surface 3. The conductive material may be copper or tungsten. The side surface of the hole may be smoother after forming of the dielectric layer than beforehand. Plasma enhanced chemical vapor deposition can be performed at a pressure of between 1 and 20 Torr.

In other words, the invention offers a method for fabricating a through wafer via at low temperature, with patterns of a few μm or tens of μm, with high form factor, higher than 5, often higher than 8, with an electrically insulating barrier deposited with best possible conformity on the walls of the hole and the least possible at the bottom of the hole. A semiconductor wafer 1 is provided with a through via, the via having a diameter of between 10 and 50 μm and length longer than 50 μm, the via comprising a central conductor, a barrier layer of thickness between 1 and 100 nm and a continuous insulating layer in the thickness of the wafer body, the insulating layer having a thickness of between 100 nm and 1000 nm. The drift is less than 16%. The minimum thickness of the insulating layer around the barrier layer is 30% thicker than the minimum thickness of the insulating layer on the main surface.

By way of comparison, the inventors have determined that when depositing at a temperature between 200 and 450° C.:

PECVD deposition offers conformity of less than 30%. For an insulating layer thickness of 1 μm close to the bottom of a via, provision must be made for a total thickness of more than 6 μm to obtain 15% conformity and more than 12 μm for 7% conformity.

HPCVD deposition offers conformity of more than 40%. However since the dielectric properties are lower than with the above technique the thickness of the insulating layer close to the bottom of the via is much greater than 1 μm.

HPCVD deposition followed by PECVD deposition offers overall conformity of more than 35% and satisfactory dielectric properties. The thickness of the insulating layer close to the bottom of the via may be 1 μm, PECVD deposition following after HPCVD deposition improving the dielectric properties of the layer obtained with HPCVD deposition.

1. A method for manufacturing a semiconductor wafer comprising a conductive through via extending from a main surface of the wafer, said via having a form factor higher than five, said wafer including a dielectric layer, the method comprising:
forming at least one through hole extending from the main surface of the wafer by deep etching having a form factor higher than five in the semiconductor wafer, the hole comprising a side surface;
forming at least one dielectric layer in said hole with two treatments in a reactor under controlled pressure, one of the treatments including sub-atmospheric chemical vapor deposit of dielectric on the side surface of the hole, chemical deposition being performed at a temperature lower than 400° C. and under pressure higher than 100 Torr in said reactor, and another of said treatments including plasma enhanced chemical vapor deposit of a dielectric on the side surface of the hole, chemical deposition being performed at a pressure lower than 20 Torr in said reactor; and
filling the hole with a conductive material thereby forming a via.

2. The method of claim 1, wherein the conductive material comprises copper or tungsten, the dielectric comprises silicon dioxide and the semiconductor wafer comprises single-crystal silicon.

3. The method of claim 1, wherein the dielectric layer has a substantially cylindrical side surface to within 40%.

4. The method of claim 1, wherein sub-atmospheric chemical vapor deposition is performed on the semiconductor wafer before plasma enhanced chemical vapor deposition.

5. The method of claim 1, wherein at least one of the two treatments is implemented at a deposit rate faster than 250 nanometers per minute, preferably 300 nanometers per minute.

6. The method of claim 1, further comprising, after the forming of the dielectric layer, forming a metal layer on the dielectric layer, the metal layer forming a barrier to block diffusion of the conductive material, said metal layer comprising at least one of: Ti, TiN, Ta, TaN, and Ru.

7. The method of claim 1, wherein sub-atmospheric chemical vapor deposition is conducted at a temperature between 200 and 400° C., preferably between 250 and 350° C.

8. The method of claim 1, wherein sub-atmospheric chemical vapor deposition is conducted under a pressure of between 100 and 600 Torr, preferably between 200 and 400 Torr.

9. The method of claim 1, wherein sub-atmospheric chemical vapor deposition and/or plasma enhanced chemical vapor deposition are conducted under a flow of precursor at between 500 and 2000 mg/min, preferably between 1000 and 1500 mg/min.

10. The method of claim 1, wherein sub-atmospheric chemical vapor deposition is conducted under a flow of O₂/O₃ at between 1000 and 3000 scc/min, preferably between 1500 and 2000 scc/min.

11. The method of claim 1, wherein plasma enhanced chemical vapor deposition is conducted at a temperature between 200 and 400° C., preferably between 200 and 300° C.

12. The method of claim 1, wherein plasma enhanced chemical vapor deposition is conducted at a pressure of between 1 and 20 Torr, preferably between 5 and 10 Torr.

13. The method of claim 1, wherein plasma enhanced chemical vapor deposit is conducted using plasma having a power of between 300 and 1200 W, preferably between 500 and 800 W.

14. The method of claim 1, wherein plasma enhanced chemical vapor deposition is performed under a flow of O₂/O₃ of between 500 and 1500 scc/min, preferably between 800 and 1200 scc/min.

15. The method of claim 1, wherein plasma enhanced chemical vapor deposition and/or sub-atmospheric chemical vapor deposition are conducted under a flow of O₂/O₃ with 10 to 18% O₃, preferably 12 to 16% O₃.

16. The method of claim 1, wherein the via has a diameter of between 10 and 50 μm and a length longer than 50 μm.

17. The method of claim 1, wherein the side surface of the hole is smoother after the formation of the dielectric layer than beforehand.
